(19) United States
(12) Patent Application Publication
(10) Pub. No.: US 2011/0133837 A1
(43) Pub. Date: Jun. 9, 2011

(54) VARIABLE GAIN AMPLIFIER

(76) Inventor: Hiroshi KOMORI, Shiga (JP)

(21) Appl. No.: 12/899,196

(22) Filed: Oct. 6, 2010

(30) Foreign Application Priority Data
Dec. 8, 2009 (JP) 2009-278742

(51) Int. Cl. H03F 3/45; H03G 3/30

(52) U.S. Cl. 330/254

(57) ABSTRACT

A gain variable range of a variable gain amplifier is increase and a non-linear distortion is reduced at the same time. The variable gain amplifier includes an operational amplifier, a variable resistive circuit which includes a plurality of variable resistive elements connected together in series, each having a resistance value corresponding to a given control voltage, and is connected between an input terminal and an output terminal of the operational amplifier, and a control circuit configured to generate a plurality of control voltages each corresponding to a gain control signal, having an offset corresponding to a DC voltage difference between input and output of the operational amplifier, and apply the plurality of control voltages to the plurality of the variable resistive elements, respectively.

### CROSS-REFERENCE TO RELATED APPLICATION

This application claims priority to Japanese Patent Application No. 2009-278742 filed on Dec. 8, 2009, the disclosure of which including the specification, the drawings, and the claims is hereby incorporated by reference in its entirety.

### BACKGROUND

The present disclosure relates to a variable gain amplifier, and more particularly, relates to a variable gain amplifier using a variable resistive element.

In recent years, mobile wireless devices have been widely used. It is required that a transmitter used in a mobile wireless device is configured to control the level of a transmission signal in a wide range so that the transmission signal does not interfere radio signals from other users' devices, and thus more users can be accommodated. It is also required that a receiver used in a mobile wireless device is configured to control the level of a reception signal so that an input signal to a demodulator is at a predetermined level, and thus the input signal can be demodulated with high accuracy while the generation of noise and distortion is reduced. To meet the above-described desires, a variable gain amplifier having a wide input dynamic range and a good linear characteristic is needed.

FIG. 5 is a diagram illustrating a configuration of a known variable gain amplifier. In FIG. 5, each reference symbol beside each element indicates a resistance value of the element. In the variable gain amplifier, when control voltages V1 and V2 are at the H level which is sufficiently high, resistance values RM1 and RM2 are substantially zero, and a gain is a minimum value represented by 1/(R1·(1/R2+1/R3+1/R4)). On the other hand, when the control values V1 and V2 are at the L level, the resistance values RM1 and RM2 are high impedance, and the gain is a maximum value represented by R2/R1. The gain can be set at any value between the maximum value and the minimum value by appropriately changing the resistance values RM1 and RM2 by way of the control voltages V1 and V2.

### SUMMARY

In the variable gain amplifier, a non-linear distortion which results from the non-linear characteristics of the resistance values RM1 and RM2 of transistors controlled by control voltages V1 and V2 occurs between a maximum gain and a minimum gain. To reduce the non-linear distortion, resistance values R3 and R4 have to be increased so that a voltage applied between a source and a drain of each of the transistors controlled by the control voltages V1 and V2 is as low as possible. On the other hand, to increase a variable gain range, the resistance values R3 and R4 have to be reduced to be as small as possible. As described above, increase in gain variable range and reduction in non-linear distortion are in a trade-off relationship in the variable gain amplifier.

An example variable gain amplifier includes: an operational amplifier; a variable resistive circuit which includes a plurality of variable resistive elements connected together in series, each having a resistance value corresponding to a given control voltage, and is connected between an input terminal and an output terminal of the operational amplifier; and a control circuit configured to generate a plurality of control voltages each corresponding to a gain control signal, having an offset corresponding to a DC voltage difference between input and output of the operational amplifier, and apply the plurality of control voltages to the plurality of the variable resistive elements, respectively. Note that the offset is preferably a voltage corresponding to a value obtained by dividing the DC voltage difference by the number of variable resistive elements.

Thus, the resistance value of the variable resistive circuit can be reduced to substantially zero, so that the minimum gain of the variable gain amplifier can be extended to be substantially zero. Moreover, the DC voltage difference between the input and output of the variable gain amplifier can be substantially equally divided between each of the variable resistive elements, and thus, a voltage across each of the variable resistive elements is reduced, so that a non-linear distortion can be reduced.

### BRIEF DESCRIPTION OF THE DRAWINGS

FIG. 1 is a configuration diagram of a variable gain amplifier according to an example embodiment of the present invention.

FIG. 2 is a configuration diagram illustrating an example configuration of a control circuit.

FIG. 3 is a configuration diagram illustrating another example configuration of the control circuit.

FIG. 4 is a configuration diagram of a variable gain amplifier according to a variation.

FIG. 5 is a configuration diagram of a known variable gain amplifier.

### DETAILED DESCRIPTION

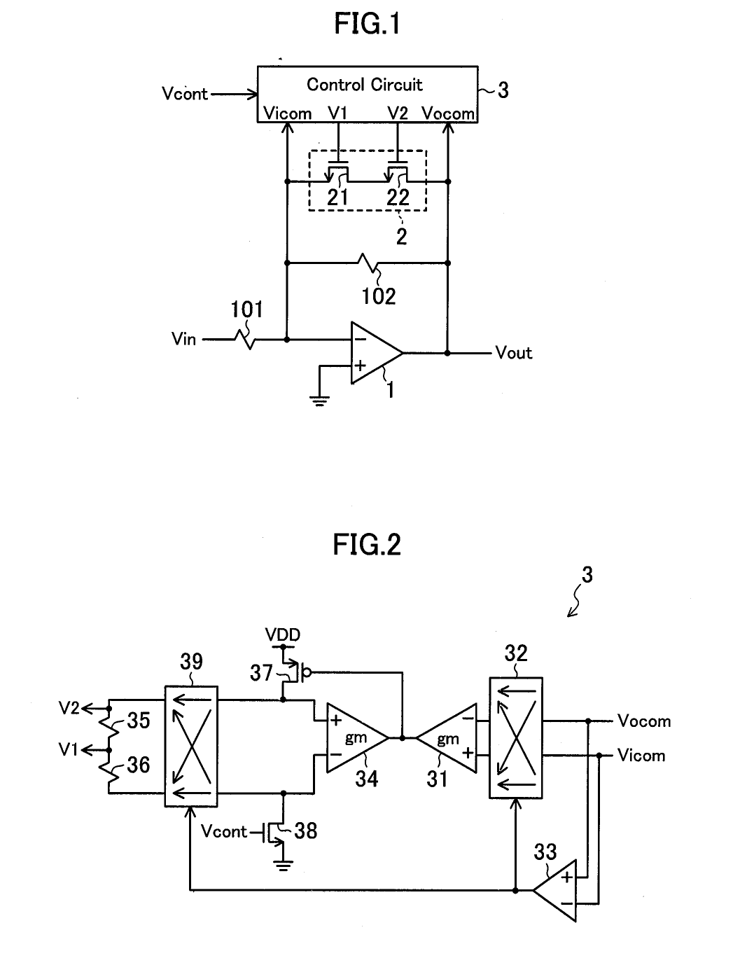

FIG. 1 illustrates a configuration of a variable gain amplifier according to an example embodiment of the present invention. An operational amplifier 1 amplifies a signal Vin input via a resistive element 101 to output a signal Vout. A resistive element 102 is connected between an input terminal and an output terminal of the operational amplifier 1. Furthermore, a variable resistive circuit 2 is connected in parallel to the resistive element 102. For example, the variable resistive circuit 2 can be comprised of variable resistive elements 21 and 22 which have resistance values corresponding to control voltages V1 and V2 and are connected together in series. The variable resistive elements 21 and 22 can be realized, for example, by operating each of NMOS transistors in which V1 and V2 are applied at gates thereof in a triode region. A control circuit 3 generates V1 and V2 each corresponding to a gain control signal Vcont. Note that the resistive element 102 may be omitted.

When V1 and V2 are at the H level which is sufficiently high, the resistance values of the variable resistive elements 21 and 22 are substantially zero, so that the gain of the variable gain amplifier of this embodiment is substantially zero, i.e., the minimum value. On the other hand, when V1 and V2 are at the L level, the variable resistive elements 21 and 22 are high impedance. In this case, assuming that the resistance values of the resistive elements 101 and 102 are R1 and R2, the gain of the variable gain amplifier is the maximum value represented by R2/R1. The gain can be set at any value between the maximum and the minimum by appropriately changing V1 and V2 in a range in which each of the NMOS transistors serving as the variable resistive elements 21 and 22 is operated in a triode region.

In this embodiment, the variable resistive elements 21 and 22 are connected together in series, and thus, a voltage across each of the variable resistive elements 21 and 22 is low. Accordingly, each of the NMOS transistors serving as the variable resistive elements 21 and 22 can be operated so that a preferable linear characteristic can be achieved. Therefore, a non-linear distortion at an intermediate gain can be reduced. However, assuming that an input DC voltage Vicom and an output DC voltage Vocom of the operational amplifier 1 applied as DC bias voltages to both ends of the variable resistive elements 21 and 22 connected in series are different from each other, when V1 and V2 are the same voltage, gate-source voltages of the variable resistive elements 21 and 22 are different from each other, and thus, the transistors cannot be operated to have the same drain-source voltages. That is, a voltage across one of the variable resistive elements 21 and 22 is relatively higher than a voltage across the other one, and a non-linear distortion might occur. For example, when Vicom<Vocom, a source voltage of the variable resistive element 22 is relatively high, and thus, a gate-source voltage is relatively low. As a result, a resistance value of the variable resistive element 22 is larger than that of the variable resistive element 21, and a DC bias applied to the both ends of the variable resistive elements 21 and 22 is increased. Thus, a non-linear distortion might occur.

Therefore, the control circuit 3 sets an offset for V1 and V2 according to a DC voltage difference between the input and output of the operational amplifier 1. Preferably, the offset is ½ of the difference between Vicom and Vocom. Thus, the gate-source voltages of the variable resistive elements 21 and 22 are equal to each other, so that a DC bias can be applied equally between the drain and the source of each of the variable resistive elements 21 and 22. As a result, the drain-source voltages of the variable resistive elements 21 and 22 are equal to each other and are the minimum value, and thus, a non-linear distortion can be reduced.

### Example Configuration of Control Circuit 3

FIG. 2 illustrates an example configuration of the control circuit 3. Vicom and

Vocom are input to a gm amplifier 31 via a swap circuit 32. The swap circuit 32 swaps inputs to the gm amplifier 31 according to an output of a comparator 33 for comparing the magnitudes of Vicom and Vocom. For example, Vicom and Vocom are input respectively to a positive phase input terminal and a reverse phase input terminal of the gm amplifier 31 when Vicom<Vocom, and are input respectively to the reverse phase input terminal and the positive phase input terminal of the gm amplifier 31 when Vicom>Vocom.

A voltage across resistive elements 35 and 36 connected together in series is input to a gm amplifier 34. A voltage at one end (a connection node with the resistive element 36) of the resistive element 35 is output as V1, and a voltage at the other end is output as V2.

Outputs of the gm amplifiers 31 and 34 are connected together, and the gm amplifiers 31 and 34 output currents having opposite polarities each other. A variable current source 37 outputs currents corresponding to voltages at a common output terminal of the gm amplifiers 31 and 34. The variable current source 37 can be comprised of a PMOS transistor in which a voltage at the common output terminal of the gm amplifiers 31 and 34 is input at a gate thereof.

A variable resistive circuit 38 having a resistance value corresponding to Vcont is connected in series to the resistive elements 35 and 36. The variable resistive circuit 38 can be realized, for example, by operating an NMOS transistor in which Vcont is input at a gate thereof in a triode region.

Destinations to which the both ends of the resistive elements 35 and 36 connected in series are connected can be swapped by a swap circuit 39. For example, the resistive elements 35 and 36 are connected respectively to the variable current source 37 and the variable resistive circuit 38 when Vicom<Vocom, and are connected respectively to the variable resistive circuit 38 and the variable current source 37 when Vicom>Vocom.

In the above-described configuration, the voltage across the resistive elements 35 and 36 is caused to be equal to a difference between Vicom and Vocom by negative feedback control by the gm amplifiers 31 and 34 and the variable current source 37. Therefore, the resistance values of the resistive elements 35 and 36 are caused to be equal to each other, and thus, an offset for V1 and V2 can be set to be ½ of the difference between Vicom and Vocom. Furthermore, Vcont is appropriately changed, and thus, V1 and V2 can be increased or reduced with the offset maintained.

Note that if the magnitude relationship between Vicom and Vocom is not changed, the swap circuits 32 and 39 and the comparator 33 can be omitted. Also, the ratio between the resistance values of the resistive elements 35 and 36 does not have to be exactly 1:1, but may be close to 1:1, for example, 99:101, and the like.

### Another Example Configuration of Control Circuit 3

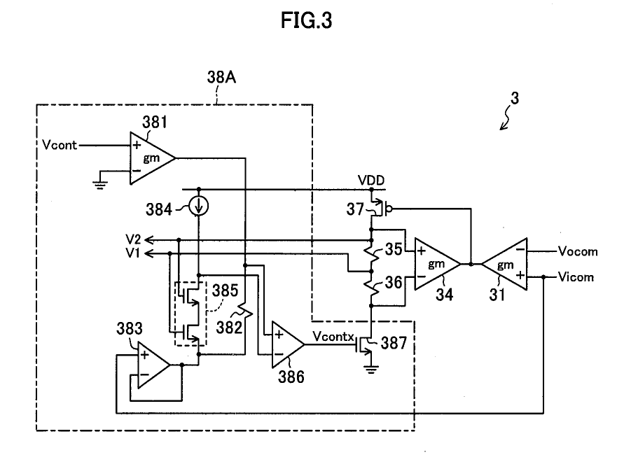

FIG. 3 illustrates another example configuration of the control circuit 3. In the control circuit 3 having this example configuration, the swap circuits 32 and 39 and the comparator 33 of the foregoing example configuration are omitted, and furthermore, the variable resistive circuit 38 is replaced with a variable resistive circuit 38A. A gm amplifier 381 outputs a current corresponding to Vcont. One end of a reference resistive element 382 is connected to an output terminal of the gm amplifier 381, and the other end thereof is connected to an output terminal of a voltage buffer circuit 383. A lower one of Vicom and Vocom is input to the voltage buffer circuit 383. In this example, for convenience, Vicom<Vocom is assumed, and thus, Vicom is input to the voltage buffer circuit 383.

A replica circuit 385 of the variable resistive circuit 2 is connected between a constant current source 384 and the output terminal of the voltage buffer circuit 383. An operational amplifier 386 outputs a control voltage Vcontx corresponding to a difference between a voltage across the reference resistive element 382 and a voltage across the replica circuit 385. A variable resistive element 387 has a resistance value corresponding to Vcontx. The variable resistive element 387 can be realized, for example, by operating an NMOS transistor in which Vcontx is input at a gate thereof in a triode region.

In the above-described configuration, the voltage across the replica circuit 385 is caused to be equal to the voltage across the reference resistive element 382 by a negative feedback control of the operational amplifier 386. That is, the resistance value of the replica circuit 385 can be varied according to Vcont, and furthermore, the resistance value of the variable resistive circuit 2 can be varied according to Vcont. And also, the resistance values of the variable resistive elements 21 and 22 can be caused to be proportional to the resistance value of the reference resistive element 382 at any fabrication and temperature variations.

Although resistance values of elements formed on a semiconductor substrate vary from one production lot to another because of fabrication variations, variation amounts of elements of the same kind are substantially equal. Similarly, variations in elements of the same kind due to temperature change are equal. Therefore, the variable resistive circuit 2, the replica circuit 385, the resistive elements 101, 102, 35, 36, and 382 may be formed on the same semiconductor substrate. Thus, resistance values of all elements vary in the same direction due to fabrication variations and temperature change, so that, at any gain settings, the gain of the variable gain amplifier can be constant relative to fabrication variations and temperature change. Note that highly accurate external resistive elements may be used for the resistive elements 101, 102, 35, 36, and 382.

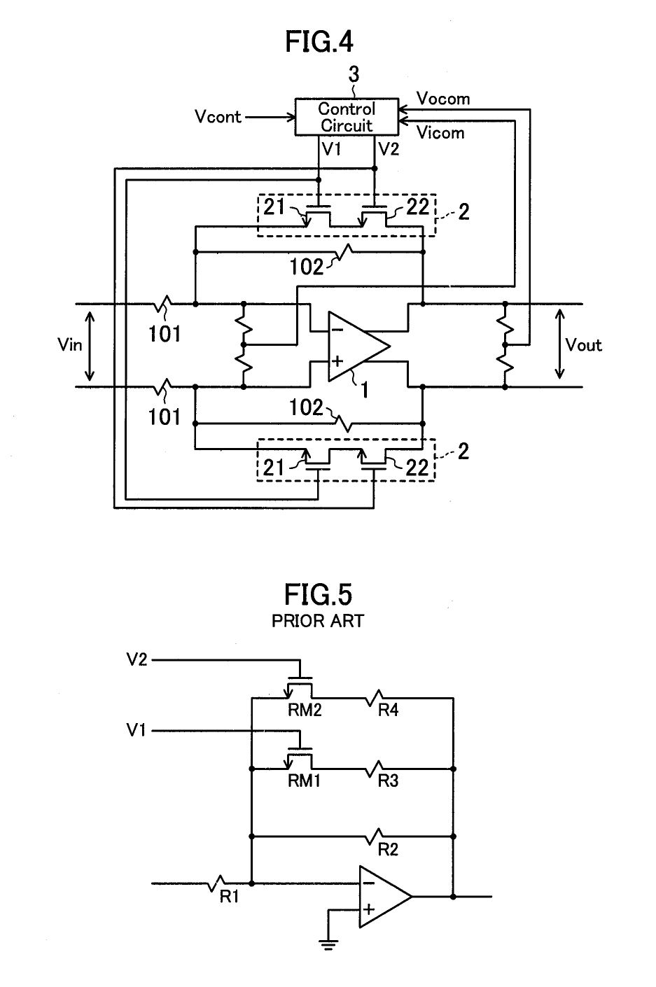

A variable gain amplifier according to this embodiment may be varied as a differential amplifier. FIG. 4 illustrates a configuration of a variable gain amplifier according to a variation. In a differential amplifier, common voltages obtained by performing resistance voltage division to differential signals Vin and Vout serve as Vicom and Vocom.

As described above, according to this embodiment, a non-linear distortion at an intermediate gain can be reduced while a gain variable range of a variable gain amplifier is increased. Specifically, a very small gain can be controlled with high accuracy. Furthermore, a gain can be controlled relative to fabrication variations and temperature change with high accuracy in a stable manner.

Note that the variable resistive circuit 2 may be configured to include three or more variable resistive elements connected together in series. In this case, the number of control voltages is increased according to the number of the variable resistive elements to set an offset corresponding to a value obtained by dividing a DC voltage difference between the input and output of the operational amplifier 1 by the number of the variable resistive elements. For example, when an additional variable resistive element is provided between the variable resistive elements 21 and 22 of FIG. 1, an additional resistive element is also provided between the resistive elements 35 and 36 of FIG. 2, and a voltage at one end of the additional resistive element is output as another control voltage.

Also, the variable resistive circuit 2 may be provided not in the negative feedback unit of the operational amplifier 1 but in an input unit thereof. In this case, the resistive element 101 may be omitted.

What is claimed is:

1. A variable gain amplifier, comprising:
an operational amplifier;
a variable resistive circuit which includes a plurality of variable resistive elements connected together in series, each having a resistance value corresponding to a given control voltage, and is connected between an input terminal and an output terminal of the operational amplifier; and
a control circuit configured to generate a plurality of control voltages each corresponding to a gain control signal, having an offset corresponding to a DC voltage difference between input and output of the operational amplifier, and apply the plurality of control voltages to the plurality of the variable resistive elements, respectively.

2. The variable gain amplifier of claim 1, wherein
the offset is a voltage corresponding to a value obtained by dividing the DC voltage difference by the number of variable resistive elements.

3. The variable gain amplifier of claim 1, wherein
the control circuit includes
a plurality of resistive elements connected together in series,
a second variable resistive circuit connected in series to the plurality of resistive elements and having a resistance value corresponding to the gain control signal,
a first gm amplifier configured to output a current corresponding to the DC voltage difference,
a second gm amplifier whose output is connected to an output of the first gm amplifier and which is configured to output a current corresponding to a voltage across the plurality of resistive elements and having an opposite polarity to that of the first gm amplifier, and
a variable current source connected to the plurality of resistive elements and configured to output currents corresponding to voltages at a common output terminal of the first and second gm amplifiers, and
voltages of connection nodes of the plurality of resistive elements are output as the plurality of control voltages.

4. The variable gain amplifier of claim 3, wherein
the second variable resistive circuit includes
a constant current source,
a third gm amplifier configured to output a current corresponding to the gain control signal,
a voltage buffer circuit configured to receive a lower one of an input DC voltage and an output DC voltage of the operational amplifier,
a replica circuit of the variable resistive circuit, the replica circuit being connected between the constant current source and an output terminal of the voltage buffer circuit,
a reference resistive element connected between an output terminal of the third gm amplifier and the output terminal of the voltage buffer circuit,
a second operational amplifier configured to output a voltage corresponding to a difference between a voltage across the reference resistive element and a voltage across the replica circuit, and
a variable resistive element connected in series to the plurality of resistive elements and having a resistance value corresponding to an output of the second operational amplifier.

5. The variable gain amplifier of claim 4, wherein
the variable resistive circuit and the replica circuit are formed on a same semiconductor substrate.

6. The variable gain amplifier of claim 3, wherein
the control circuit includes
a comparator configured to compare magnitudes of an input DC voltage and an output DC voltage of the operational amplifier to each other,
a first swap circuit configured to swap inputs to the first gm amplifier according to an output of the comparator, and
a second swap circuit configured to swap, according to the output of the comparator, destinations to which both ends of the plurality of resistive elements connected together in series are connected.
